(19) United States
(12) Patent Application Publication
(10) Pub. No.: US 2006/0220548 A1
(43) Pub. Date: Oct. 5, 2006

(54) Self-light emitting panel and method for fabricating the same

(75) Inventor: Michio Menda, Yamagata (JP)

Correspondence Address: ARENT FOX PLLC, 1050 CONNECTICUT AVENUE, N.W., SUITE 400, WASHINGTON, DC, 20036, US

(73) Assignee: TOHOKU PIONEER CORPORATION

(21) Appl. No.: 11/389,130

(22) Filed: Mar. 27, 2006

(30) Foreign Application Priority Data
Mar. 29, 2005 (JP) 2005-95548

(51) Int. Cl. H01J 1/62

(52) U.S. Cl. 313/512

(57) ABSTRACT

A self-light emitting panel includes a self-emission device portion formed of a single or a plurality of self-emission devices disposed on a substrate, and a sealing structure for sealing the self-emission device portion. The sealing structure includes a buffer layer for covering an upper portion and a side portion of the self-emission device portion, a barrier layer formed on the buffer layer, another buffer layer for covering the barrier layer and the first buffer layer, and another barrier layer, formed on the second buffer layer, for covering the first barrier layer and an edge of the first barrier layer. Thereby, the self-light emitting panel can be further reduced in thickness by employing the sealing structure with no sealed space formed therein to provide an enhanced barrier performance using a multi-layered barrier layer structure.

### BACKGROUND OF THE INVENTION

1. Field of the Invention

The present invention relates to a self-light emitting panel and a method for fabricating the panel.

The present application claims priority from Japanese Patent Application No. 2005-095548, the disclosure of which is incorporated herein by reference.

2. Description of the Related Art

Research and development has been intensively carried out on a self-light emitting panel, typified by an organic EL (Electroluminescence) panel, in expectation of its application to the display of cellular phones, slim TV sets, or personal digital assistants, as well as an on-board functional display, e.g., the functional display portion of an instrumentation panel such as a speedometer or an electric appliance, a thin-film display, or an outdoor information sign or illuminations.

Such a self-light emitting panel includes a single or a plurality of self-emission devices fabricated on a substrate. The self-emission device includes an organic EL device as well as light-emitting devices such as LEDs (Light Emitting Diodes) or FEDs (Field Emission Displays).

Referring to the organic EL device as an example, the self-emission device is configured to have an organic EL functioning layer (including a light-emission layer and formed of a low molecular weight organic material or a polymer organic material) disposed between the anode (or a hole injection electrode) and the cathode (or an electron injection electrode). A voltage applied between the anode and cathode electrodes will cause the holes injected and transported from the anode to the organic EL functioning layer and the electrons injected and transported from the cathode to the organic EL functioning layer to recombine with each other in the organic layer (the emission layer) and thereby provide a desired emission.

In general, to maintain the emission characteristics of the self-emission device, such a self-light emitting panel employs a sealing structure for isolating the self-emission device from outside air. In the case of the organic EL panel, the organic layer and the electrode exposed to the atmospheric moisture and oxygen would cause degradation in the emission characteristics of the self-emission device. It is thus inevitable in the current step of development to provide sealing means for isolating the organic EL device from outside air.

In general, a sealing structure was employed for the organic EL panel, in which a sealing member made of metal or glass is affixed to the substrate having the organic EL device formed thereon to create a sealed space in which a desiccant can be placed around the organic EL device. However, attempts have been made to further reduce the thickness of the panel and employ the top emission scheme by which light is transmitted from the organic EL device on the substrate through the side opposite to the substrate. In this context, such a structure has been developed in which the organic EL device on the substrate is directly covered with a sealing material.

As shown in FIG. 1A, disclosed in Japanese PCT International Application Publication No. 2003-532260 is a sealing structure in which a display device J11 on a substrate J10 is covered with a single layer or a plurality of layers such as a barrier layer J12 and a polymer layer J13 laminated thereon. Here, the barrier layer J12 may be made of a metal oxide, metal nitride, metal carbide, metal oxynitride, metal oxyboride, or a combination thereof. On the other hand, the polymer layer J13 may be made of an acrylate containing monomer, oligomer, or resin.

Furthermore, as shown in FIG. 1B, disclosed in Japanese Patent Application Publication No. Hei 10-275680 is a sealing structure in which an organic EL device J21 has a transparent electrode, a hole transport layer, an emission layer, and a metal cathode, which are formed on a glass substrate J20, and the organic EL device J21 is covered with a protective layer J22. Here, the protective layer J22 has a stack of layers such as an insulating layer J22a and a metal layer J22b.

According to the conventional technique described in Japanese Translation of PCT International Application No. 2003-532260, the barrier layer is disposed directly on the device formed on the substrate, thereby causing the stress produced during the formation of the barrier layer to be applied to the surface of the device. This in turn causes strain in the device and thus degradation in the performance thereof as well as the means and step for forming the device to be restricted in order to-alleviate the stress. Furthermore, typically, there are bumps and dips formed on the surface of the device due to the presence of the TFT elements, insulating films, insulating ribs and the like. Accordingly, when the barrier layer is formed directly thereon, portions reduced in thickness or in some cases, pinholes may be formed, thereby providing an insufficient barrier performance.

Furthermore, as shown in Japanese Patent Application Publication No. Hei 10-275680, even when the insulating film is formed on the surface of the device and the metal film is then formed thereon, the insulating film provided by the conventional technique cannot assure a sufficient thickness. Thus, this may result in the bumps and dips on the surface of the device causing variations in thickness of the metal film, thereby providing an insufficient barrier performance in the same manner as described in Japanese PCT International Application Publication No. 2003-532260.

Furthermore, to form the metal film, it is necessary to prevent the metal film from being brought into contact with the electrode traces formed on the substrate. This may cause a non-barrier region to be formed at edges a₁ and a₂ of the insulating film (see FIG. 1B), there by making it difficult to prevent the intrusion of moisture.

In particular, as shown in Japanese Patent Application Publication No. Hei 10-275680, the multi-layered structure formed of the insulating films and the metal films may cause the aforementioned non-barrier region to be formed respectively at the edge side portions a₁ and a₂ of each insulating film. Accordingly, in the presence of a pinhole in the first metal film, a moisture intrusion path would be formed from the sides as shown by the arrows and thus cause the effect of the multi-layered structure to be ruined, thereby providing an inefficiently enhanced barrier performance.

### SUMMARY OF THE INVENTION

The present invention was developed in view of the aforementioned problems. It is therefore an object of the present invention to provide a self-light emitting panel that can be further reduced in thickness by employing a sealing structure with no sealed space formed therein. The self-light emitting panel is intended to prevent the stress produced upon forming the barrier layer from being applied to the device, thereby avoiding degradation in performance due to strain resulting from the stress. The panel is also intended to remove the effects of bumps and dips of the surface of the device, thereby assuring a sufficient barrier performance. The panel is further intended to positively enhance the barrier performance using a multi-layered structure of the barrier layer.

To achieve such an object, the self-light emitting panel and the method for fabricating the panel according to the present invention includes at least the following arrangements set forth in the following aspects of the invention.

Namely, according to one of the aspects of the present invention, a self-light emitting panel is provided, including a self-emission device portion formed of a single or a plurality of self-emission devices disposed on a substrate, and a sealing structure for sealing the self-emission device portion. In this panel, the sealing structure at least comprises: a first buffer layer for covering an upper portion and a side portion of the self-emission device portion; a first barrier layer formed on the first buffer layer; a second buffer layer for covering the first barrier layer and an edge of the first buffer layer; and a second barrier layer, formed on the second buffer layer, for covering the first barrier layer and an edge of the first barrier layer.

Furthermore, according to another aspect of the present invention, a method for fabricating a self-emission device is provided, including the steps of: forming a self-emission device portion of a single or a plurality of self-emission devices disposed on a substrate; and sealing the self-emission device portion. In this method, the sealing step forms a sealing structure by affixing a film to the substrate so as to cover the self-emission device portion, wherein the film is obtained by laminating a buffer layer having an adhesion function and a barrier layer having a moisture blocking function. Furthermore, the sealing structure at least comprises: a first buffer layer for covering an upper portion and a side portion of the self-emission device portion, a first barrier layer formed on the first buffer layer, a second buffer layer for covering the first barrier layer and an edge of the first buffer layer, and a second barrier layer, formed on the second buffer layer, for covering the first barrier layer and an edge of the first barrier layer.

Furthermore, according to still another aspect of the present invention, a method for fabricating a self-emission device is provided, including the steps of: forming a self-emission device portion of a single or a plurality of self-emission devices disposed on a substrate; and sealing the self-emission device portion. In this method, the sealing step forms a sealing structure by depositing a buffer layer having an adhesion function and a barrier layer having a moisture blocking function on the substrate so as to cover the self-emission device portion. Furthermore, the sealing structure at least comprises: a first buffer layer for covering an upper portion and a side portion of the self-emission device portion, a first barrier layer formed on the first buffer layer, a second buffer layer for covering the first barrier layer as well as covering an edge of the first buffer layer, and a second barrier layer, formed on the second buffer layer, for covering the first barrier layer and an edge of the first barrier layer.

### BRIEF DESCRIPTION OF THE DRAWINGS

These and other objects and advantages of the present invention will become clear from the following description with reference to the accompanying drawings, wherein:

FIGS. 1A and 1B are explanatory views of two different examples showing the conventional technique;

FIG. 2 is an explanatory view showing a self-light emitting panel according to an embodiment of the present invention;

FIG. 3 is an explanatory view showing an end portion structure of a self-light emitting panel according to an embodiment of the present invention;

FIG. 4 is a flaw chart showing a part of a method for fabricating a self-light emitting panel according to an embodiment of the present invention;

FIG. 5A is an explanatory view showing a method for fabricating a self-light emitting panel according to an example of the present invention;

FIG. 5B is an explanatory view showing a method for fabricating a self-light emitting panel according to another example of the present invention; and

FIG. 6 is a flow chart showing a part of a method for fabricating a self-light emitting panel according to another embodiment of the present invention.

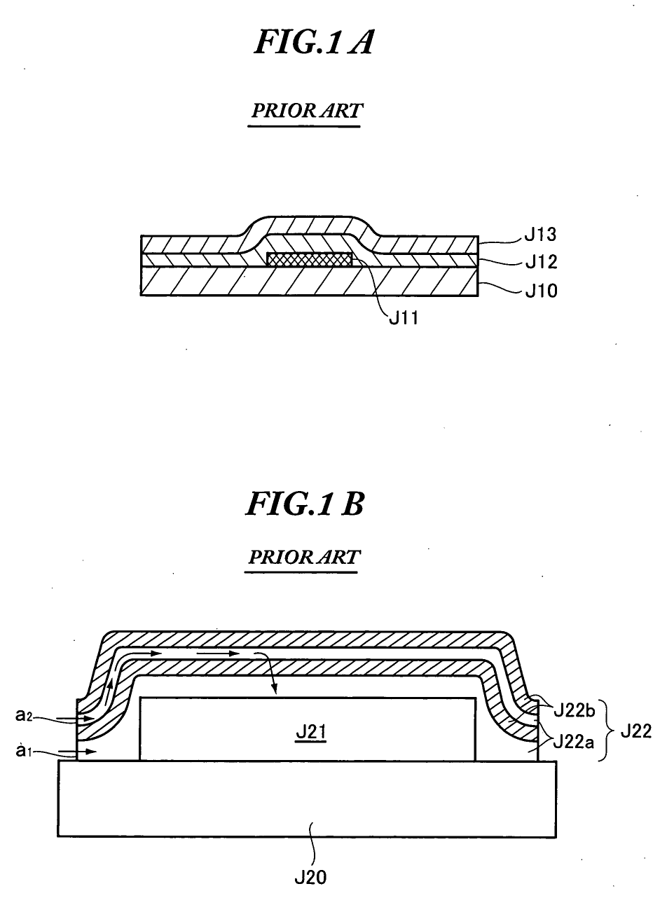

### DETAILED DESCRIPTION OF THE PREFERRED EMBODIMENTS

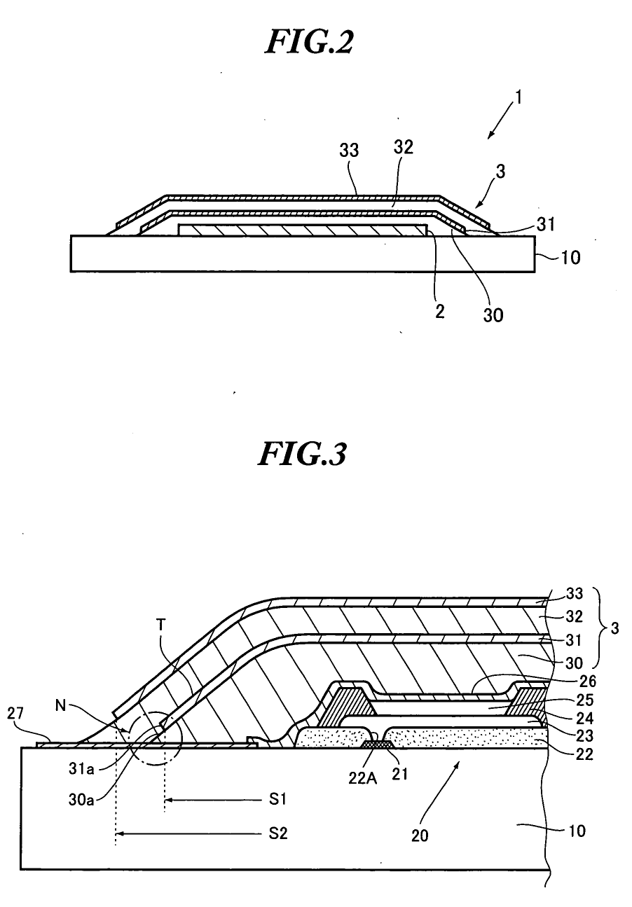

Now, the present invention will be described below in more detail with reference to the accompanying drawings in accordance with the embodiments. FIG. 2 is an explanatory view showing a self-light emitting panel according to an embodiment of the present invention. A self-light emitting panel 1 includes a self-emission device portion 2 formed of a single or a plurality of self-emission devices disposed on a substrate 10, and a sealing structure 3 for sealing the self-emission device portion 2.

On the other hand, the sealing structure 3 has at least a first buffer layer 30 for covering the upper and side portions of the self-emission device portion 2; a first barrier layer 31 formed on the first buffer layer 30; a second buffer layer 32 for covering the first barrier layer 31 as well as an edge of the first buffer layer; and a second barrier layer 33, formed on the second buffer layer 32, for covering the first barrier layer 31 and an edge of the first barrier layer 31.

Here, although the example of a double structure including the buffer layer 30/barrier layer 31 and the buffer layer 32/barrier layer 33 is shown, it is also possible to employ a structure provided with a further increased number of layers. That is, in such a case, a structure includes an overlying buffer layer (32) for covering the underlying barrier layer (31) as well as covering an edge of the underlying buffer layer (30), and an overlying barrier layer (33), formed on the overlying buffer layer (32), for covering the underlying barrier layer (31) and an edge of the underlying barrier layer (31). It is thus possible to employ a triple-layered structure, a quadruple-layered structure, or a structure having a further increased number of layers. In all cases, the structure is configured such that an upper barrier layer is formed so as to cover the edge portion of a lower barrier layer, and the coverage area of the upper barrier layer is wider than the coverage area of the lower barrier layer.

The buffer layers 30 and 32 according to an embodiment of the present invention can be formed mainly of a material which has an adhesion function and serves to flatten underlying bumps and dips. More specifically, it is possible to employ an adhesive material layer made of a polymeric material. The materials include, but not specifically being limited to, an optically cured type, a thermosetting type, or a two-part chemically cured type adhesive, such as an epoxy resin, acrylic resin, or silicone resin, a thermoplastic resin, polyimide, poly-urea, or acrylate containing polymer.

Furthermore, the barrier layer 31 (33) according to an embodiment of the present invention is a moisture blocking layer made of, e.g., a metal, a metal compound, or a non-metal material. More specifically, the barrier layers 31 and 33 are formed of a metal such as aluminum and stainless steel, a metal oxide such as alumina, titania, and tin oxide, a metal nitride such as aluminum nitride and silicon nitride, and a non-metal compound such as a glass or ceramic material.

One of the features according to an embodiment of the present invention is not to form the barrier layers 31 and 33 directly on and thereby provide sealing to the self-emission device portion 2. This makes it possible to avoid degradation in performance of the self-emission device, which would otherwise result from the application of stress upon forming the barrier layer. Furthermore, the intervention of the buffer layers 30 and 32 makes it possible to flatten the bumps and dips present on the self-emission device portion 2, thereby allowing the barrier layers 31 and 33 to be formed thereon uniformly in thickness. This makes it possible to avoid degradation in barrier performance caused by a portion partially reduced in thickness or pinholes, thus providing a high sealing performance.

Another feature of the sealing structure according to an embodiment of the present invention is in an end portion structure of a multi-layered structure. FIG. 3 is an explanatory view showing an end portion structure of a self-light emitting panel according to an embodiment of the present invention. Here, shown is an end portion where a self-emission device 20 or one component of the self-emission device portion 2 is formed. At this end portion, also formed are the first buffer layer 30, the first barrier layer 31, the second buffer layer 32, and the second barrier layer 33.

This self-emission device 20 is formed as follows. For example, a flattening film 22 having a connection hole 22A is formed on a TFT element 21 deposited on the substrate 10. On the flattening film 22, a bottom electrode 23 is patterned for each self-emission device 20 so as to connect to the TFT element 21 via the connection hole 22A. A partition is then provided by an insulating film 24 around the bottom electrode 23. An emission functioning layer 25 is deposited on the bottom electrode 23 within the opening partitioned by the insulating film 24. A top electrode 26 is then deposited on the emission functioning layer 25, and a lead electrode 27 is formed to connect to the top electrode.

The end portion of the self-emission device portion 2 including such a self-emission device 20 is covered with the buffer layer 30 and the barrier layer 31. At this stage, when the barrier layer 31 is a conductive film (such as a metal film), it is necessary to prevent it from being brought into contact with the lead electrode 27 formed on the substrate 10. Accordingly, an edge 31a of the barrier layer 31 is not in contact with the substrate 10, thus allowing a non-barrier region N to be formed at an edge 30a of the buffer layer 30. When the buffer layer 30 and the barrier layer 31 are stacked in multiple layers, such non-barrier regions N configured to individually contact with outside air would cause the multi-layered structure not to effectively provide an enhanced barrier performance just as in the conventional technique.

In this context, according to an embodiment of the present invention, the second buffer layer 32 is formed to cover the first barrier layer 31 as well as the edge 30a of the first buffer layer. Furthermore, the second barrier layer 33 formed on the second buffer layer 32 is formed to have a slightly wider coverage area so as to cover the first barrier layer 31 and the edge 31a of the first barrier layer 31. That is, as shown in FIG. 3, with the first barrier layer 31 covering an area S₁, the second barrier layer 33 would be formed to cover an area S₂ wider than the area S₁.

This allows the non-barrier region N produced upon forming the first barrier layer 31 to be covered with the overlying buffer layer 32 and barrier layer 33. Accordingly, the non-barrier region resulting from the formation of a multi-layered structure can be restricted to the uppermost barrier layer 33, thereby allowing the multi-layered structure to efficiently provide an enhanced barrier performance. At this time, the uppermost barrier layer may be a moisture blocking layer formed of an insulating material, and the edge thereof may be brought into intimate contact with the substrate 10, thereby allowing a non-barrier region exposed to outside air to be completely eliminated. This in turn allows the multi-layered structure to provide the sealing structure with a further enhanced barrier performance.

Another feature according to an embodiment of the present invention is that the aforementioned buffer layers 30 and 32, especially the first buffer layer 30 has a tapered edge portion T that is gradually reduced in thickness towards an end portion of the substrate 10. The tapered edge portion T formed in this manner at the end portion of the buffer layer 30 allows the barrier layer 31 to be formed thereon in a uniform thickness up to the vicinity of the edge 30a of the buffer layer 30. When no tapered edge portion T is provided at the end portion of the buffer layer 30 and thus the end portion is cut sharply, it is very difficult to form the barrier layer 31 on the side of the end portion. This would result in a large non-barrier region being formed corresponding to the thickness of the buffer layer 30, and thus a sufficient barrier performance cannot be provided against the sideward intrusion of moisture. According to an embodiment of the present invention, the presence of the tapered edge portion T minimizes non-barrier regions.

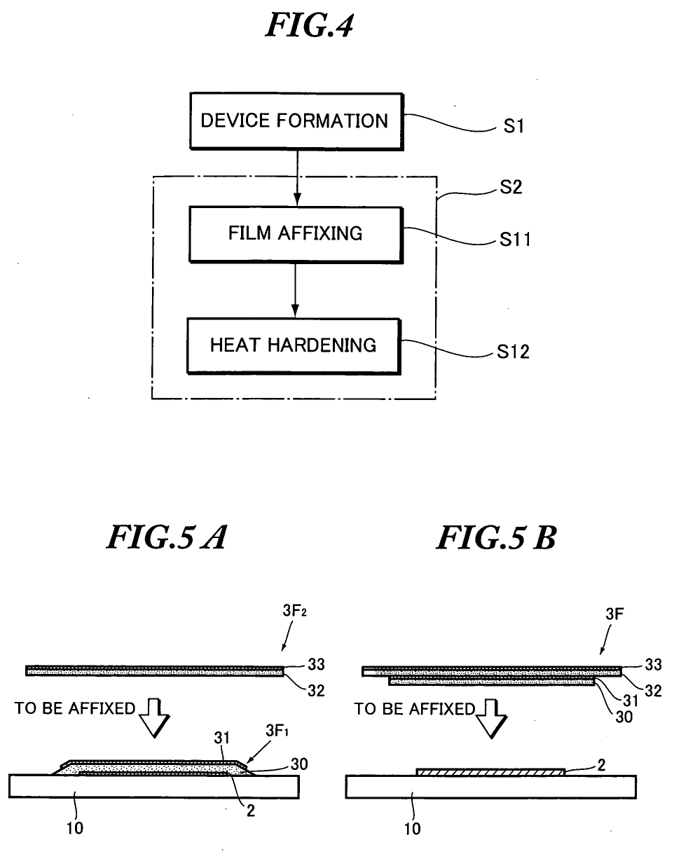

Now, an explanation will be given to a method for fabricating the self-light emitting panel according to an embodiment of the present invention. FIG. 4 is an explanatory view showing an embodiment of the fabricating method. The method for fabricating the self-light emitting panel according to this embodiment of the present invention includes a device formation step S1 for forming the self-emission device portion 2 with a single or a plurality of the self-emission devices 20 disposed on the substrate 10, and a sealing step S2 for sealing the self-emission device portion 2. By way of example, in this sealing step S2, the aforementioned sealing structure is formed by affixing films 3F, 3F₁, and 3F₂ to the substrate 10 so as to cover the self-emission device portion 2. The films 3F, 3F₁, and 3F₂ each include a stack of the buffer layer(s) 30 and/or 32 having an adhesion function and the barrier layer(s) 31 and/or 33 having a moisture blocking function. That is, the sealing step S2 to be performed here has a film affixing step S11 and a heat hardening step S12 to be performed after the film affixing step.

A more specific explanation will be given to the film affixing step S11 with reference to FIGS. 5A and 5B. Here, two methods are conceivably employed to form the aforementioned sealing structure. One method is shown in FIG. 5A. That is, first, the first film 3F₁ is affixed onto the substrate 10 to cover the self-emission device portion 2. The film 3F₁ has a stack of the buffer layer 30 serving as an adhesive layer and the barrier layer 31 made of filmed metal foil. After the film 3F₁ has been affixed, the second film 3F₂ is affixed onto the first film 3F₁. The film 3F₂ has a stack of the buffer layer 32 serving as an adhesive layer and the barrier layer 33 made of filmed metal foil. Here, to form the aforementioned end portion structure, the area of the barrier layer 33 in the second film 3F₂ is made greater than the area of the barrier layer 31 in the first film 3F₁.

On the other hand, the other method is shown in FIG. 5B. That is, the multi-layered film 3F is formed in advance by sequentially laminating the first buffer layer 30/the first barrier layer 31/the second buffer layer 32/the second barrier layer 33. The film 3F is affixed at a time to the substrate 10 so as to cover the self-emission device portion 2. At this time, to form the aforementioned end portion structure, the area of the overlying barrier layer 33 is made greater than the area of the underlying barrier layer 31.

According to a fabricating method having such a sealing step S2, the sealing step S2 can be completed using relatively simple equipment. This allows the manufacturing time to be reduced and the self-light emitting panel to be fabricated with improved productivity. It is thus possible to provide a multi-layered sealing structure with the non-barrier region minimized.

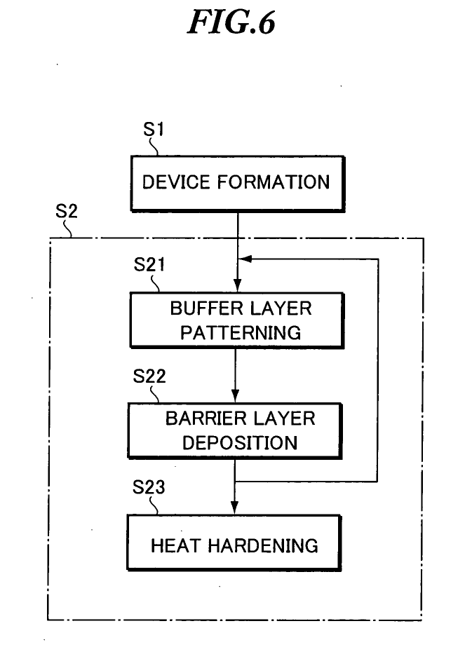

FIG. 6 is an explanatory view showing another embodiment of a method for fabricating a self-light emitting panel. Like the aforementioned method, a method for fabricating a self-light emitting panel according to this embodiment of the present invention has the device formation step S1 for forming the self-emission device portion 2 with a single or a plurality of the self-emission devices 20 disposed on the substrate 10, and the sealing step S2 for sealing the self-emission device portion 2. In this sealing step S2, the aforementioned sealing structure is formed by depositing the buffer layers 30 and 32 and the barrier layers 31 and 33 on the substrate 10 so as to cover the self-emission device portion 2. That is, the sealing step S2 to be performed here repeats a buffer layer patterning step S21 and a barrier layer deposition step S22, and thereafter the heat hardening step S23 is performed.

In the buffer layer patterning step S21, for example, a limited coating area is coated by a coating method such as roll coating, spin coating, or spray coating. Alternatively, a printing method such as the screen printing may also be employed to deposit the buffer layer 30 of an adhesive layer on a predetermined region on the self-emission device portion 2.

In the barrier layer deposition step S22, a mask or the like is employed to define the range of deposition to form the barrier layers 31 and 33 having a predetermined coverage area by a deposition method such as vapor deposition, sputtering, or CVD.

According to the fabricating method having such a sealing step S2, the buffer layer 30 is formed and then the barrier layer 31 is deposited thereon. Accordingly, any deposition method can be employed to deposit the barrier layer 31 to prevent an adverse effect such as strain due to stress on the self-emission device portion 2. It is thus possible to provide a multi-layered sealing structure with the non-barrier region minimized.

In the aforementioned description, the formation of a non-barrier region was explained in accordance with the embodiment in which the first barrier layer 31 is formed of a conductive film such as a metal film. However, the first barrier layer 31 may also be formed of an insulating film. Even in this case, when an attempt is made to form the first buffer layer 30 and then the first barrier layer 31 thereon, it will be found difficult to bring the edge 31a of the first barrier layer 31 into intimate contact with the substrate 10. Thus, like the aforementioned case, the non-barrier region N (or a non-intimate contact portion into which moisture can easily intrude) will be formed. Accordingly, the aforementioned description can also hold true in the case of the first barrier layer 31 being made of an insulating film also.

Now, by way of example, the structure and material of an organic EL device employed as the self-emission device 20 will be shown below.

First, the organic EL device will be described hereinafter. In general, the organic EL device is configured to have an organic EL functioning layer disposed between the anode (or a hole injection electrode) and the cathode (or an electron injection electrode). Application of a voltage between the electrodes will cause the holes injected and transported from the anode to the organic EL functioning layer and the electrons injected and transported from the cathode to the organic EL functioning layer to recombine with each other in this layer (the emission layer) and thereby provide emission. As shown in FIG. 3, by way of example, the following specific structures and materials may be applicable to the organic EL device (the self-emission device 20) in which the bottom electrode 23, the emission functioning layer 25 of the organic EL functioning layer, and the top electrode 26 are deposited on the substrate 10.

In particular, to employ the bottom emission structure for transmitting light through the substrate 10, the substrate 10 may be a transparent, flat, film-like substrate, and made of glass or plastics. On the other hand, to employ the top emission structure for transmitting light through the side opposite to the substrate 10, the substrate 10 is not necessarily required to be transparent.

For the bottom electrode 23 or the top electrode 26, one is to be set as the cathode and the other as the anode. In this case, the anode maybe preferably formed of a high work function material. That is, the anode is often made of a metal film such as chromium (Cr), molybdenum (Mo), nickel (Ni), or platinum (Pt); or alternatively a transparent conductive film of an oxide metal film such as ITO or IZO. On the other hand, the cathode may preferably be formed of a low work function material. In particular, the cathode can be made of a low work function metal such as an alkali metal (Li, Na, K, Rb, or Cs), an alkaline earth metal (Be, Mg, Ca, Sr, or Ba), or a rare earth metal, a compound thereof, or an alloy containing them. When both the bottom electrode 23 and the top electrode 26 are formed of a transparent material, a reflective film may also be provided on the electrode opposite to the light transmission side.

Furthermore, the lead electrodes 27 extended from the top electrode 26 (or the bottom electrode 23) is provided to connect between the self-light emitting panel 1 and drive means, such as an IC or a driver, for driving the panel. The lead electrode is preferably made of a low resistance metal material such as Ag, Cr, or Al, or an alloy thereof.

In general, to form the bottom electrode 23 and the lead electrode 27, for example, a thin film for the bottom electrode 23 and the lead electrode 27 is formed of ITO or IZO by vapor deposition or sputtering, and then patterned by photolithography. As the bottom electrode 23 and the lead electrode 27 (especially, the lead electrode required to be reduced in resistance), it is possible to employ a two-layer structure with a low resistance metal, such as Ag, an Ag alloy, Al, or Cr, deposited on the aforementioned underlying layer such as of ITO or IZO. Alternatively, a three-layer structure can also be employed in which a material, such as Cu, Cr, or Ta, having good resistance to oxidation is further deposited as a protective layer such as for Ag.

In general, when the bottom electrode 23 is the anode and the top electrode 26 is the cathode, employed as the organic EL functioning layer (the emission functioning layer 25) deposited between the bottom electrode 23 and the top electrode 26 is a stacked structure of the hole transport layer/the emission layer/the electron transport layer (when the bottom electrode 23 is the cathode and the top electrode 26 is the anode, employed is the stacked structure with the same layers but stacked in the reverse order). The emission layer, the hole transport layer, and the electron transport layer may be each formed not only in a single layer but also in multiple layers. Furthermore, either the hole transport layer or the electron transport layer may be eliminated or both of them may be eliminated leaving only the emission layer. As the organic EL functioning layer, it is also possible to insert an organic functioning layer such as a hole injection layer, an electron injection layer, a hole barrier layer, or an electron barrier layer depending on the application.

The material for the organic EL functioning layer can be selected, as appropriate, depending on the application of the organic EL device. By way of example, some of the materials are shown below but the invention is not limited thereto.

The hole transport layer is only required to have a high hole mobility and thus can be formed of any material selected from conventionally known compounds. Examples of the material for the hole transport layer include organic materials, e.g., porphyrin compounds such as copper phthalocyanine, aromatic triamines such as 4,4′-bis[N-(1-naphthyl)-N-phenylamino]-biphenyl (NPB), stilbene compounds such as 4-(di-p-tolylamino)-4′-[4-(di-p-tolylamino) styryl]stilbenzene, triazole derivatives, and styrylamine compounds. It is also possible to use a polymer dispersed material obtained by a low molecular weight hole transport organic material being dispersed in a polymer material such as polycarbonate. Preferably employed is a material whose glass transition temperature is higher than the temperature at which the sealing resin is hardened by heating, e.g., including 4,4′-bis[N-(1-naphthyl)-N-phenylamino]-biphenyl (NPB).

The emission layer may be formed of a well-known luminescent material, and specific examples include aromatic dimethylidyne compounds such as 4,4′-bis (2,2′-diphenylvinyl)-biphenyl (DPVBi); styryl benzene compounds such as 1,4-bis(2-methylstyryl)benzene; fluorescent organic compounds such as triazole derivatives including 3-(4-biphenyl)-4-phenyl-5-t-butylphenyl-1,2,4-triazole (TAZ), anthraquinone derivatives, and fluorenone derivatives; fluorescent organometal compounds such as (8-hydroxyquinolinato)aluminum complex (Alq₃); polymer materials such as poly p-phenylene vinylene (PPV) based, polyfluorene based, and polyvinyl carbazole (PVK) based materials; and organic materials such as platinum complexes and iridium complexes, capable of using phosphorescence from a triplet exciton for emission (Japanese Translation of PCT International Application No. 2001-520450). The emission layer may be formed only of the aforementioned luminescent material, or may also include a hole transport material, an electron transport material, an additive (such as a donor or an acceptor), or a luminescent dopant. These materials may also be dispersed in a polymer material or an inorganic material.

The electron transport layer is only required to serve to transfer the electrons injected from the cathode to the emission layer and thus can be formed of any material selected from conventionally known compounds. Examples of the material for the electron transport layer include organic materials such as nitro-substituted fluorenone derivatives and anthraquino-dimethane derivative, metal complexes such as 8-quinolinol derivatives, and metal phthalocyanine.

The aforementioned hole transport layer, emission layer, and electron transport layer can be formed by a wet process, including a coating method such as the spin coating method and the dipping method or a printing method such as the ink-jet method and the screen printing method, or by a dry process, including the vapor deposition method and the laser transfer method, discussed later.

The self-emission device portion 2 including the self-emission device 20 may form a single organic EL device or may also be provided with a desired patterned structure to form a plurality of pixels. In the latter case, the organic EL device may display in a single emission color or in two or more emission colors. In particular, to realize an organic EL panel for providing a plurality of emission colors, the following schemes are available. That is, a scheme (the separate coloring scheme) is available for forming emission functioning layers in two or more colors, including a scheme for forming three types of emission functioning layers corresponding to R, G, and B. Another scheme available is to combine an emission functioning layer of a single color, such as white or blue, with a color filter or a color conversion layer of a fluorescent material (the CF scheme or CCM scheme). Another scheme available is to irradiate the emission area of a single-color emission functioning layer with electromagnetic waves to implement multiple emissions (the photobleaching scheme). Another scheme available is the laser transfer scheme in which low molecular weight organic materials having different emission colors are pre-deposited on different films and then thermally transferred using a laser to one substrate.

In the case of the self-light emitting panel 1 according to an embodiment of the present invention, the organic EL device may transmit light according to the bottom emission scheme by which light is transmitted through the substrate 10 or the top emission scheme by which light is transmitted through the side opposite to the substrate 10 (i.e., through the top electrode 26). Furthermore, the self-emission device 20 (the organic EL device) may be driven by the aforementioned TFT element 21 according to the active drive scheme, or according to the passive drive scheme.

According to such an embodiment of the present invention, the sealing structure with no sealed space formed therein, unlike the conventional one, can be employed, thereby allowing the panel to be further reduced in thickness. Furthermore, since the barrier layers 31 and 33 are not formed directly on the self-emission device portion 2, the stress caused upon forming the barrier layer will never be applied to the self-emission device 20, thereby preventing degradation in the performance of the self-emission device 20 due to strain resulting from the stress.

Furthermore, since the barrier layers 31 and 33 are formed via the buffer layers 30 and 32, the effect caused by the bumps and dips of the surface of the self-emission device portion 2 can be eliminated to provide a uniform thickness to the barrier layers 31 and 33, thereby ensuring a sufficient barrier performance. Furthermore, since the barrier layers 31 and 33 are formed in a multi-layered structure with the non-barrier region minimized, the multi-layered structure can positively provide an enhanced barrier performance.

Furthermore, since the buffer layers 30 and 32 are simultaneously formed in a multi-layered structure, it can be ensured that the self-emission device portion 2 is protected even when a mechanical pressure is applied to the self-emission device portion 2 or a sharp pin or the like contacts therewith.

While there has been described what are at present considered to be preferred embodiments of the present invention, it will be understood that various modifications may be made thereto, and it is intended that the appended claims cover all such modifications as fall within the true spirit and scope of the invention.

What is claimed is:

1. A self-light emitting panel including a self-emission device portion formed of a single or a plurality of self-emission devices disposed on a substrate, and a sealing structure for sealing the self-emission device portion, the sealing structure at least comprising:
a first buffer layer for covering an upper portion and a side portion of the self-emission device portion;
a first barrier layer formed on the first buffer layer;
a second buffer layer for covering the first barrier layer and an edge of the first buffer layer; and
a second barrier layer, formed on the second buffer layer, for covering the first barrier layer and an edge of the first barrier layer.

2. The self-light emitting panel according to claim 1, comprising:
an overlying buffer layer for covering the underlying barrier layer and the edge of the underlying buffer layer; and
an overlying barrier layer, formed on the overlying buffer layer, for covering the underlying barrier layer and the edge of the underlying barrier layer.

3. The self-light emitting panel according to claim 1, wherein the edge of the first barrier layer is not in contact with the substrate, and a non-barrier region is formed on the edge of the first buffer layer.

4. The self-light emitting panel according to claim 1, wherein
the buffer layer is formed of a polymer adhesive material layer for flattening a bump and a dip on a surface of the self-emission device portion.

5. The self-light emitting panel according to claim 1, wherein
the buffer layer has a tapered edge portion gradually reduced in thickness towards an end portion of the substrate.

6. The self-light emitting panel according to claim 2, wherein
at least one of the barrier layers is a moisture blocking layer formed of a metal or a metal compound.

7. The self-light emitting panel according to claim 6, wherein
an uppermost layer of the barrier layers is a moisture blocking layer formed of an insulating material, and the edge of the barrier layer is brought into intimate contact with the substrate.

8. A method for fabricating a self-light emitting panel, including the steps of: forming a self-emission device portion of a single or a plurality of self-emission devices disposed on a substrate; and sealing the self-emission device portion, wherein
the sealing step forms a sealing structure by affixing a film to the substrate so as to cover the self-emission device portion, the film being obtained by laminating a buffer layer having an adhesion function and a barrier layer having a moisture blocking function, the sealing structure at least comprising: a first buffer layer for covering an upper portion and a side portion of the self-emission device portion, a first barrier layer formed on the first buffer layer, a second buffer layer for covering the first barrier layer and an edge of the first buffer layer, and a second barrier layer, formed on the second buffer layer, for covering the first barrier layer and an edge of the first barrier layer.

9. The method for fabricating a self-light emitting panel according to claim 8, wherein
the sealing step is performed by affixing a first film onto the self-emission device portion and then affixing a second film onto the first film, the first film being provided with the first buffer layer and the first barrier layer, and the second film being provided with the second buffer layer and the second barrier layer.

10. The method for fabricating a self-light emitting panel according to claim 8, wherein
the sealing step is performed by affixing a film onto the self-emission device portion, the film being obtained by sequentially laminating the first buffer layer, the first barrier layer, the second buffer layer, and the second barrier layer.

11. A method for fabricating a self-light emitting panel, including the steps of: forming a self-emission device portion of a single or a plurality of self-emission devices disposed on a substrate; and sealing the self-emission device portion, wherein
the sealing step forms a sealing structure by depositing a buffer layer having an adhesion function and a barrier layer having a moisture blocking function on the substrate so as to cover the self-emission device portion, the sealing structure at least comprising: a first buffer layer for covering an upper portion and a side portion of the self-emission device portion, a first barrier layer formed on the first buffer layer, a second buffer layer for covering the first barrier layer as well as covering an edge of the first buffer layer, and a second barrier layer, formed on the second buffer layer, for covering the first barrier layer and an edge of the first barrier layer.
